(19) United States
(12) Patent Application Publication
(10) Pub. No.: US 2013/0181275 A1
(43) Pub. Date: Jul. 18, 2013

(54) MANUFACTURING METHOD OF NONVOLATILE SEMICONDUCTOR STORAGE DEVICE AND A NONVOLATILE SEMICONDUCTOR STORAGE DEVICE

(71) Applicants: Yusuke Kobayashi, Mie-ken (JP); Hideo Wada, Mie-ken (JP)

(72) Inventors: Yusuke Kobayashi, Mie-ken (JP); Hideo Wada, Mie-ken (JP)

(73) Assignee: KABUSHIKI KAISHA TOSHIBA, Tokyo (JP)

(21) Appl. No.: 13/606,881

(22) Filed: Sep. 7, 2012

(30) Foreign Application Priority Data
Sep. 26, 2011 (JP) P2011-208366

(51) Int. Cl. H01L 29/788; H01L 29/66

(52) U.S. Cl. CPC H01L 29/788; H01L 29/66825
USPC 257/315; 438/257

(57) ABSTRACT

A nonvolatile semiconductor storage device has a semiconductor substrate, a gate insulating film formed on the semiconductor substrate, multiple floating gate electrodes formed on the gate insulating film, an inter-electrode insulating film formed on the multiple floating gate electrodes, and word lines formed on the inter-electrode insulating film. The word lines have lower and upper layers containing polysilicon doped with an impurity and are formed with a separating layer between the lower layer and the upper layer. A portion of the separating layer is located between multiple floating gate electrodes, and the height of the lower layer is less than the height of the upper layer.

### CROSS-REFERENCE TO RELATED APPLICATION

This application is based upon and claims the benefit of priority from Japanese Patent Application No. 2011-208366, filed Sep. 26, 2011; the entire contents of which are incorporated herein by reference.

### FIELD

Embodiments described herein relate to a manufacturing method of a nonvolatile semiconductor storage device and a nonvolatile semiconductor storage device.

### BACKGROUND

In a NAND type flash memory device or some other nonvolatile semiconductor storage device, a floating gate electrode is arranged between the control gate electrode and the semiconductor substrate; and as a designated voltage is applied on the control gate electrode, electric charge is stored in the floating gate electrode. As a result, information can be stored in the floating gate electrode. Each floating gate electrode faces an adjacent floating gate electrode via an interlayer insulating film, and a silicon thermal oxide film is formed as the tunnel oxide film between the floating gate electrode and the semiconductor substrate.

The control gate electrodes and floating gate electrodes are made of polysilicon doped with phosphorus (P) or some other impurity. In order to meet the demand for finer elements, the nonvolatile semiconductor storage device should have fine width dimensions for the control gate electrodes and floating gate electrodes, and should have a small distance between neighboring floating gates.

As the nonvolatile semiconductor storage device is made finer to meet the demand, the effect of polysilicon depletion becomes significant. The cause of the depletion includes an increase in the proportion of the surface area of the gate electrodes with respect to the volume of the polysilicon accompanied by an increase in the aspect ratio of the control gate electrodes and the floating gate electrodes.

As the surface area of the gate electrode increases, the degree of release of phosphorus (P) or some other impurity doped in the polysilicon increases, and the number of free carriers in the polysilicon decreases, so that depletion can take place. As the effect of polysilicon depletion increases, the voltage applied on the floating gate electrode in a write operation decreases, so that a miswrite may take place. In order to prevent the problem of polysilicon depletion, a technology has been proposed whereby the impurity activation rate of the polysilicon can be maintained. However, this scheme is insufficient for coping with polysilicon depletion in finer semiconductor structures.

### DESCRIPTION OF THE DRAWINGS

FIG. 1 is an equivalent circuit diagram illustrating a portion of a nonvolatile semiconductor storage device according to an embodiment.

FIG. 2 is a plane view illustrating a portion of the layout of the nonvolatile semiconductor storage device.

FIG. 3A is a schematic vertical cross-sectional view taken across 3A-3A in FIG. 2. FIG. 3B is a schematic vertical cross-sectional view taken across 3B-3B in FIG. 2.

FIG. 4A and FIG. 4B show cross-sectional views of the nonvolatile semiconductor storage device taken across 3A-3A in FIGS. 2 and 3B-3B in FIG. 2, respectively, during part 1 of manufacturing.

FIG. 5A and FIG. 5B show cross-sectional views of the nonvolatile semiconductor storage device taken across 3A-3A in FIGS. 2 and 3B-3B in FIG. 2, respectively, during part 2 of manufacturing.

FIG. 6A and FIG. 6B show cross-sectional views of the nonvolatile semiconductor storage device taken across 3A-3A in FIGS. 2 and 3B-3B in FIG. 2, respectively, during part 3 of manufacturing.

FIG. 7A and FIG. 7B show cross-sectional views of the nonvolatile semiconductor storage device taken across 3A-3A in FIGS. 2 and 3B-3B in FIG. 2, respectively, during part 4 of manufacturing.

FIG. 8A and FIG. 8B show cross-sectional views of the nonvolatile semiconductor storage device taken across 3A-3A in FIGS. 2 and 3B-3B in FIG. 2, respectively, during part 5 of manufacturing.

FIG. 9A and FIG. 9B show cross-sectional views of the nonvolatile semiconductor storage device taken across 3A-3A in FIGS. 2 and 3B-3B in FIG. 2, respectively, during part 6 of manufacturing.

FIG. 10A and FIG. 10B show cross-sectional views of the nonvolatile semiconductor storage device taken across 3A-3A in FIGS. 2 and 3B-3B in FIG. 2, respectively, during part 7 of manufacturing.

FIG. 11A and FIG. 11B show cross-sectional views of the nonvolatile semiconductor storage device taken across 3A-3A in FIGS. 2 and 3B-3B in FIG. 2, respectively, during part 8 of manufacturing.

FIG. 12A and FIG. 12B show cross-sectional views of the nonvolatile semiconductor storage device taken across 3A-3A in FIGS. 2 and 3B-3B in FIG. 2, respectively, during part 9 of manufacturing.

### DETAILED DESCRIPTION

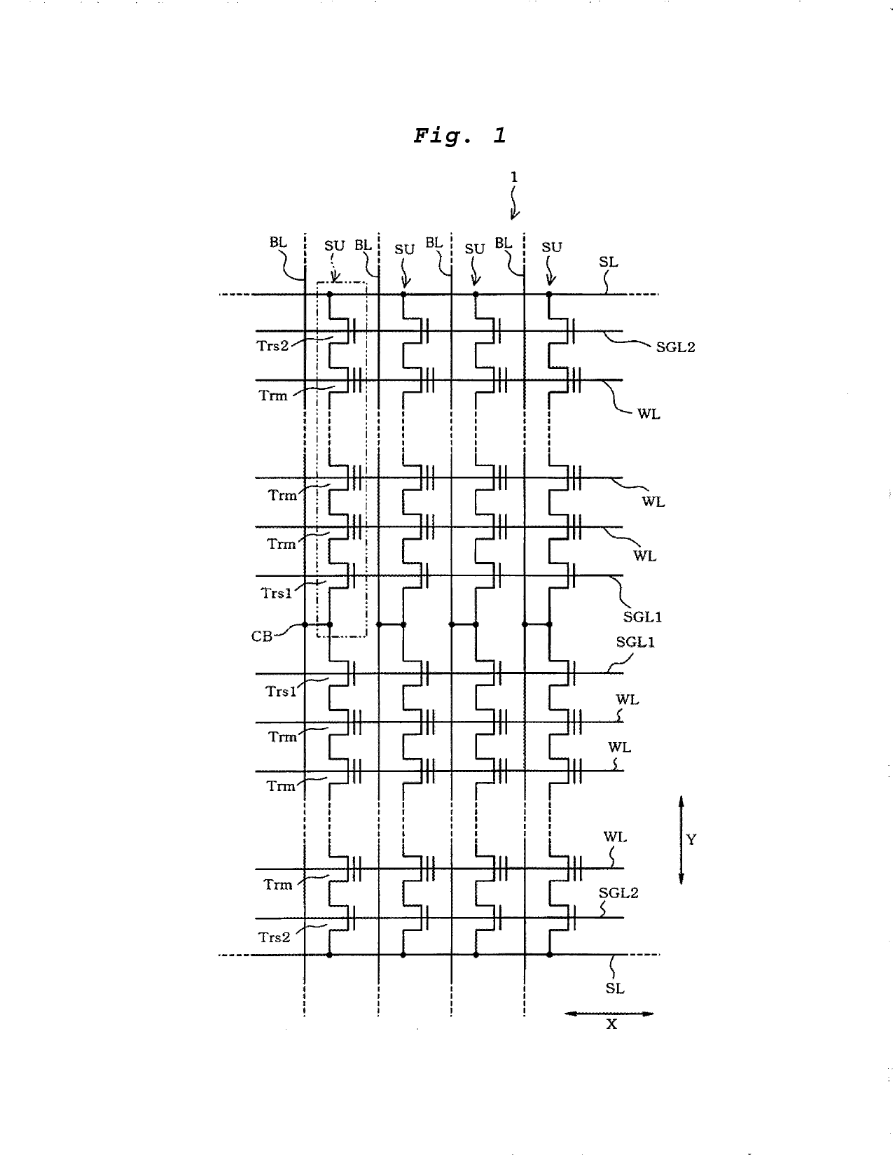

In general, one embodiment of a NAND type flash memory device that is used as semiconductor storage device will be explained with reference to FIG. 1 through FIG. 12. The same reference numbers are used throughout the various embodiments to represent the same features, and so they will not be explained in detail repeatedly. Here, the figures are schematic views, so that the relationship between the thickness and the planar dimensions and the ratio of thickness of the various layers are not to scale. In order to facilitate the explanation of the embodiments, the upper/lower left/right, higher/lower, and deep/shallow directions correspond to the relative positions with reference to the back surface side of a semiconductor substrate to be explained later. Consequently, the position relationship may be different in some cases from those cases where gravitational direction is employed as the reference direction.

According to an embodiment, there is provided a manufacturing method of a nonvolatile semiconductor storage device having control gate electrodes and floating gate electrodes, wherein it is possible to suppress depletion of polysilicon that forms the control gate electrodes.

The manufacturing method of the nonvolatile semiconductor storage device according to an embodiment includes the following operations. Agate insulating film is formed on a semiconductor substrate. Multiple floating gate electrodes are formed on the gate insulating film. An inter-electrode insulating film is formed on multiple floating gate electrodes. When wire lines containing polysilicon doped with an impurity are formed on the inter-electrode insulating film, a separating layer containing oxygen or nitrogen is formed. The separating layer separates the upper layer and lower layer of each word line from each other, and a portion of the separating layer is positioned between the multiple floating gate electrodes.

When the word lines are deposited, they are deposited so that the upper surface of a portion of the lower layer of the word line is positioned between the multiple floating gate electrodes. When oxygen is used to form the separating layer, halfway during the process of deposition of silicon, the atmosphere is substituted by an oxygen (O₂) atmosphere. For the separating layer, when nitrogen is used to form it, halfway during the deposition of silicon, the atmosphere is replaced by the nitrogen (N₂) atmosphere. In one embodiment, the upper layer of the word line is formed to be higher than the lower layer of the word line.

A nonvolatile semiconductor storage device according to an embodiment has a semiconductor substrate, a gate insulating film formed on the semiconductor substrate, multiple floating gate electrodes formed on the gate insulating film, an inter-electrode insulating film formed on the multiple floating gate electrodes, and word lines formed on the inter-electrode insulating film. The word lines are formed with a separating layer included between the upper layer and lower layer containing polysilicon doped with an impurity. The separating layer separates the upper layer and the lower layer and has a portion located between the multiple floating gate electrodes. For the word lines, the height of the lower layer is lower than the height of the upper layer.

The structure of the NAND type flash memory device according to this embodiment will be explained first. FIG. 1 is an equivalent circuit diagram illustrating a portion of the memory cell array in the memory cell region of the NAND type flash memory device 1 (corresponding to the nonvolatile semiconductor storage device).

The NAND type flash memory device 1 has the following constitution: in its memory cell array, NAND cell units SU are arranged in a matrix configuration, with each cell unit including two selecting gate transistors Trs1, Trs2, and multiple (for example, 64) memory cell transistors Trm connected in series between the selecting gate transistors Trs1, Trs2. In each of the NAND cell units SU, multiple memory cell transistors Trm share the source/drain region for the neighboring memory cell transistors.

The memory cell transistors Trm arranged in the X-direction (word line direction) shown in FIG. 1 are commonly connected with each other via word line WL. On the other hand, the selecting gate transistors Trs1 arranged in the X-direction in FIG. 1 are commonly connected with each other via the selecting gate line SGL1, and the selecting gate transistors Trs2 are commonly connected with each other via the selecting gate line SGL2. The bit line contact CB is connected to the drain region of each of the selecting gate transistors Trs1. This bit line contact CB is connected to the bit line BL that extends in the Y-direction (bit line direction) orthogonal to the X-direction shown in FIG. 1. Also, the selecting gate transistors Trs2 each are connected via the source region to the source line SL extending in the X-direction shown in FIG. 1.

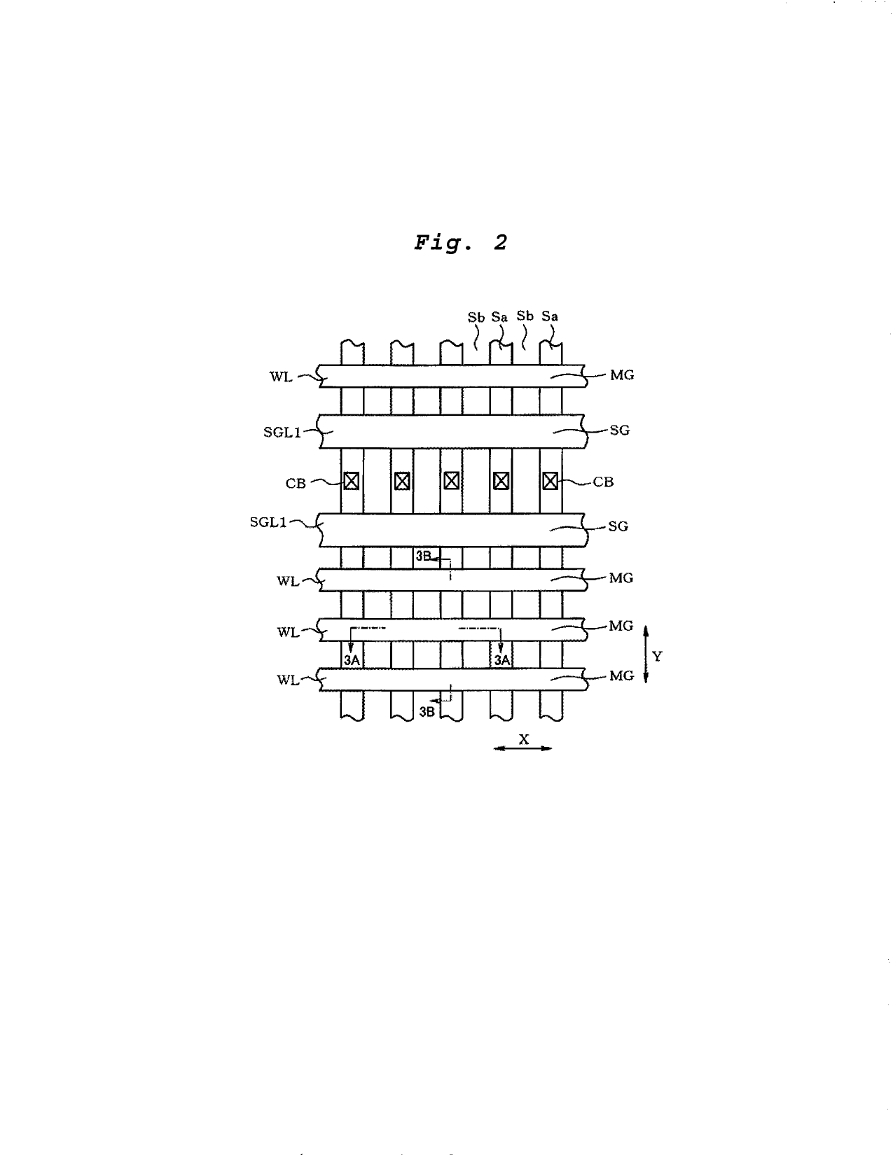

FIG. 2 is a plane view illustrating the layout of a portion of the memory cell region. As shown in FIG. 2, the element separating regions Sb with an STI (shallow trench isolation) structure are formed extending in the Y-direction as shown in FIG. 2. As shown in FIG. 2, these element separating regions Sb are formed as multiple regions with a designated spacing between them in the X-direction. As a result, the element regions Sa extend in the Y-direction as shown in FIG. 2, and the multiple element regions Sa are formed separated from each other in the X-direction.

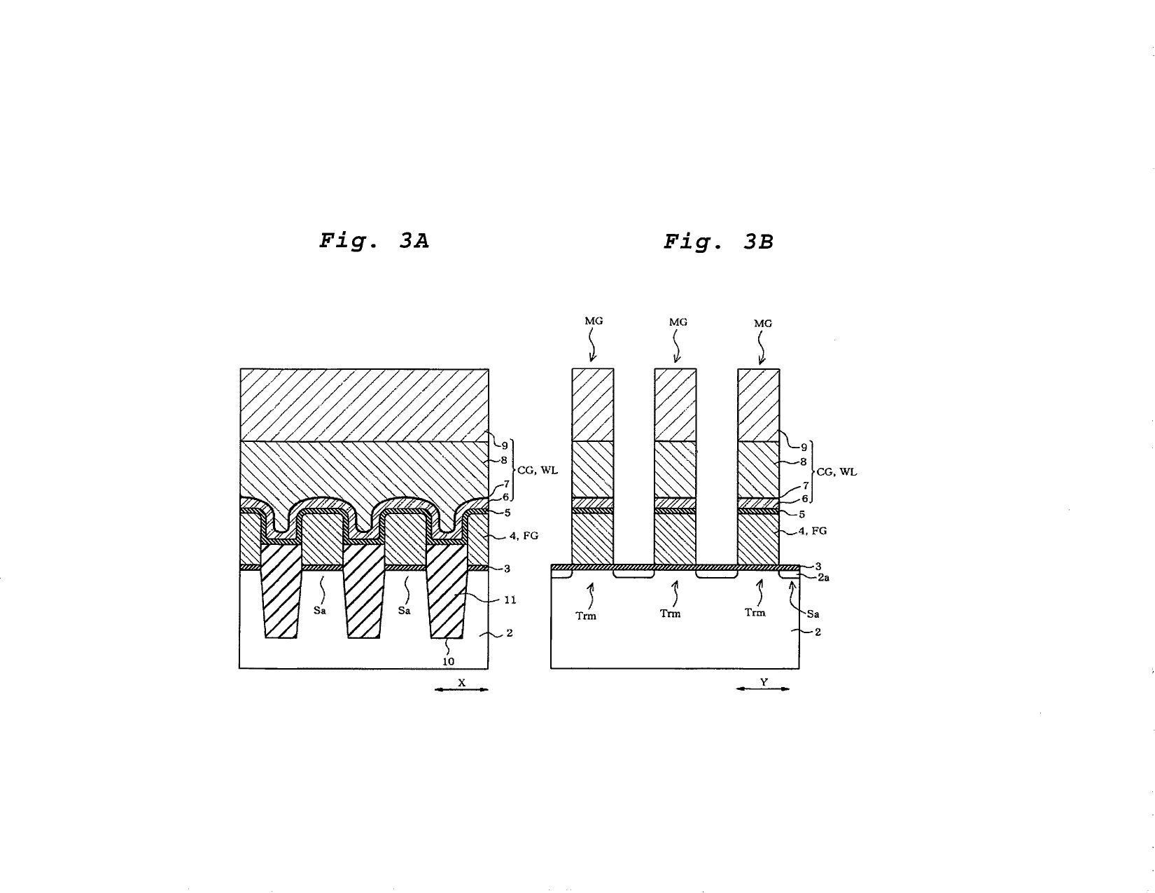

The word lines WL are formed extending in the direction crossing the element regions Sa (X-direction shown in FIG. 2). Multiple word lines WL are formed with a designated spacing in the Y-direction shown in FIG. 2. Above the element regions Sa crossing the word lines WL, the memory cell gate electrodes MG of the memory cell transistors Trm (see FIG. 3) are formed.

As shown in FIG. 1, the multiple memory cell transistors Trm adjacent to each other in the Y-direction form a NAND sequence (memory cell string). The selecting gate transistors Trs1, Trs2 are adjacent to the two outer sides in the Y-direction of the end portion memory cells of the NAND string, respectively.

Multiple selecting gate transistors Trs1 are arranged in the X-direction, and the selecting gate electrodes SG of the multiple selecting gate transistors Trs1 (see FIG. 2) are electrically connected by the selecting gate line SGL1. In the element regions Sa crossing the selecting gate line SGL1, the selecting gate electrodes SG of the selecting gate transistors Trs1 are formed.

Also, as shown in FIG. 1, multiple selecting gate transistors Trs2 are arranged in the X-direction, and the selecting gate electrodes of the multiple selecting gate transistors Trs2 (not shown in FIG. 2 and FIG. 3) are electrically connected by selecting gate line SGL2.

As shown in FIG. 1, bit line contact CB is formed between the selecting gate transistors Trs1-Trs1 of the NAND cell units SU-SU adjacent to each other in the Y-direction. Multiple bit line contacts CB are formed on the multiple element regions Sa, respectively.

FIG. 3A is a schematic vertical cross-sectional view taken across 3A-3A shown in FIG. 2. FIG. 3B is a schematic vertical cross-sectional view taken across 3B-3B in FIG. 2. FIG. 3A and FIG. 3B show the vertical cross-sectional structure of the memory cell transistors Trm. As shown in FIG. 3A, the gate insulating film 3 is formed on the semiconductor substrate 2 (such as a p-type silicon substrate). The gate insulating film 3 is made of, for example, a silicon oxide film, and it is formed along the upper surface of the semiconductor substrate 2 in the formation regions of the memory cell transistors Trm.

Each of the memory cell transistors Trm includes a memory cell gate electrode MG formed on the gate insulating film 3, as well as source/drain regions 2a formed on the outer layer of the semiconductor substrate 2 on the two flanks of the memory cell gate electrode MG.

The memory cell gate electrode MG is formed by laminating the following layers sequentially on the gate insulating film 3: floating gate electrode (charge storage layer) FG using a polysilicon layer 4 doped with phosphorus (P) or some other n-type impurity, an inter-electrode insulating film 5, and control gate electrode CG as the word line WL.

The inter-electrode insulating film 5 is an insulating film positioned between the floating gate electrode FG and the control gate electrode CG, and it becomes an inter-poly insulating film and inter-gate insulating film with the polysilicon layer held between its portions. The inter-electrode insulating film 5 may be made of a laminated structure of oxide film/nitride film/oxide film (known in the art as ONO film). One may also use a film (known in the art as NONON film) having a nitride film formed before and after formation of the ONO film. In addition, a high-dielectric-constant film containing aluminum oxide (alumina) or hafnium oxide maybe formed instead of the middle nitride film.

The control gate electrode CG as the word line WL includes the following layers: a polysilicon lower layer 6 doped with phosphorus (P) or some other n-type impurity, a separating layer 7 made of silicon oxide (SiO) layer formed on the polysilicon lower layer 6, a polysilicon upper layer 8 formed on the separating layer 7, and a silicide layer 9 prepared by siliciding the polysilicon upper layer 8. The polysilicon upper layer 8 is also doped by phosphorus (P) or some other n-type impurity. Here, the polysilicon lower layer 6 and polysilicon upper layer 8 are layers prepared by polycrystallizing the amorphous silicon doped with an impurity.

After deposition of the polysilicon lower layer 6, the separating layer 7 is formed as the sample is slightly exposed to an oxygen (O₂) atmosphere to form a very thin (about a few Å, for example, 5 Å) oxide layer as the separating layer.

The silicide layer 9 is a layer prepared by siliciding the upper portion of the polysilicon upper layer 8 by a low-resistivity metal. Here, examples of low-resistivity metals include nickel (Ni), titanium (Ti), cobalt (Co), platinum (Pt), palladium (Pd), tantalum (Ta), molybdenum (Mo), and other transition metals. The thickness of the silicide layer 9 may be adjusted appropriately corresponding to the type of the silicided metal material. Also, by selecting an appropriate type of metal material, the entire upper portion of the polysilicon upper layer 8 or the entire polysilicon upper layer 8 and polysilicon lower layer 6 may be formed as the silicide layer 9. As shown in FIG. 3B, multiple memory cell transistors Trm may be arranged adjacent to each other in the Y-direction.

In addition, although not shown in the cross-sectional view, the selecting gate electrodes of the selecting gate transistors Trs1, Trs2 have almost the same structure as that of the memory cell gate electrodes MG of the memory cell transistors Trm. The structure has the following layers laminated: a polysilicon layer 4, an inter-electrode insulating film 5, a polysilicon lower layer 6, a separating layer 7, a polysilicon upper layer 8, and a silicide layer 9. Close to the center of the inter-electrode insulating film 5, the function of the inter-electrode insulating film 5 is made invalid by having the polysilicon lower layer 6 and the polysilicon layer 4 make contact with each other.

FIG. 3B is a vertical cross-sectional view taken across 3B-3B in FIG. 2. As shown in the figure, the element regions Sa of the memory cell transistors Trm are separated from each other by element separating insulating film 11 with an STI (shallow trench isolation) structure buried in the element separating trench 10.

The element separating insulating film 11 is formed in a self-alignment way along the side surface of the floating gate electrode FG. Its upper surface is higher than the lower surface of the floating gate electrode FG and lower than the upper surface of the floating gate electrode FG. The element separating insulating film 11 is mainly made of a silicon oxide film. As shown in FIG. 3A, the inter-electrode insulating film 5 is formed along the upper surface of the element separating insulating film 11 and, at the same time, it is formed along the side surface of the upper portion of the floating gate electrode FG.

The polysilicon lower layer 6 is buried in the dip portion sandwiched between the adjacent floating gate electrodes FG-FG, so that the area of the word line WL and the floating gate electrode FG facing each other is increased, and the coupling ratio can be increased. The polysilicon upper layer 8 is laminated on the polysilicon lower layer 6 via the separating layer 7. The height of the polysilicon lower layer 6 is formed to be less than the height of the polysilicon upper layer 8 by about 1/10 in height. As a result, the mean value of the crystal grain size of polysilicon lower layer 6 is smaller than the mean value of the crystal grain size of the polysilicon upper layer 8. The cause of this phenomenon is as follows: the grain boundary (crystal grain boundary) is not continuous at the separating layer 7, and the height of the polysilicon lower layer 6 of each of the memory cell gate electrodes MG is lower than the height of the polysilicon upper layer 8.

In the following, an example manufacturing method for the nonvolatile semiconductor memory device will be explained. However, explanation is made only for the distinctive features. Consequently, other operations may be added into between the operations as long as they are conventional operations. Also, as needed, some operations may be deleted as well. Besides, as long as the operations can be actually executed, they may be replaced as needed. For the films under processing with the same functions as those of the films and layers, the same keys will be used in the explanation.

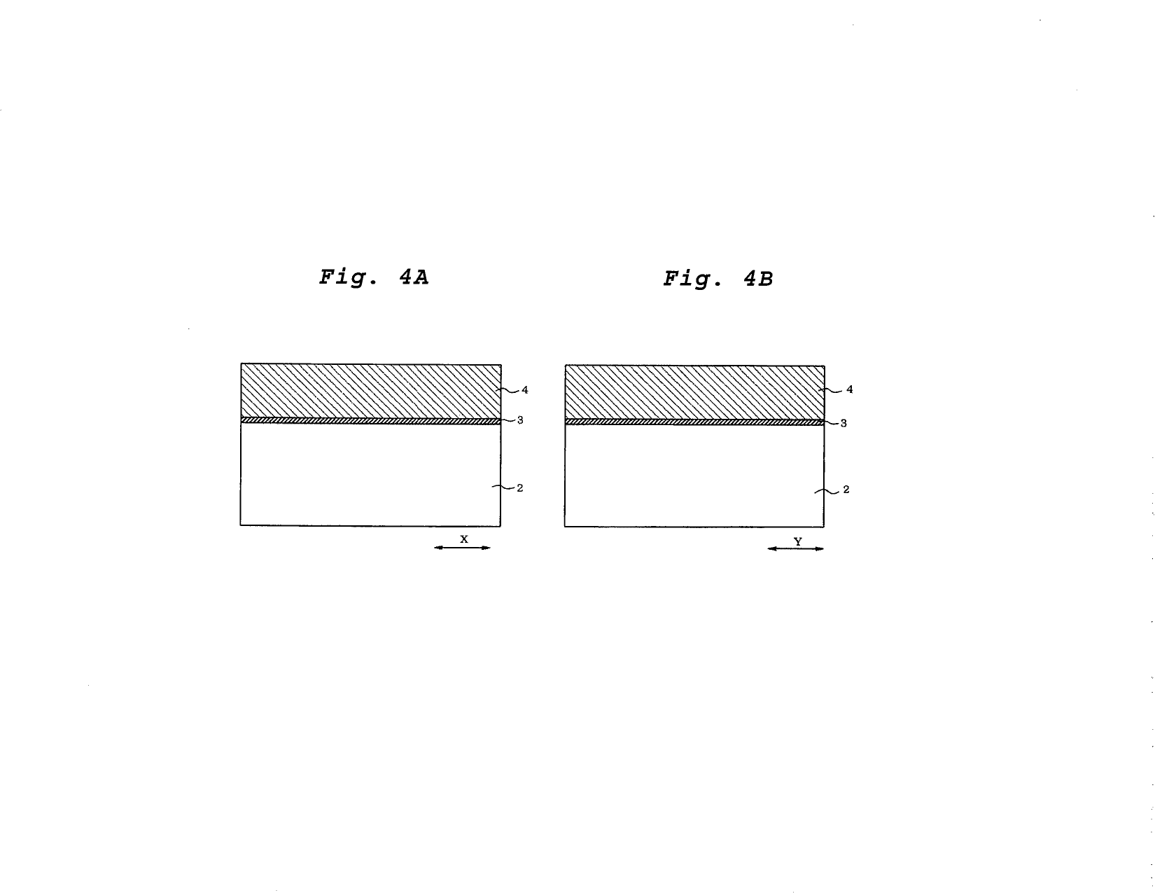

For figures with “A” attached, such as FIG. 4A to FIG. 12A, the vertical cross-sections for the parts corresponding to FIG. 3A during manufacturing are shown schematically. For figures with “B” attached, such as FIG. 4B to FIG. 12B, the vertical cross-sections for the parts corresponding to FIG. 3B during manufacturing are shown schematically.

As shown in FIG. 4A and FIG. 4B, the gate insulating film is formed on the semiconductor substrate 2. In this embodiment, as the semiconductor substrate 2 is formed from a p-type silicon substrate, the upper surface of the semiconductor substrate is subject to thermal oxidation treatment so that the silicon oxide film is formed as the gate insulating film 3. Then, the polysilicon layer 4 as the floating gate electrode FG film is deposited using the LP-CVD (chemical vapor deposition) method. In this case, phosphorus (P) is used as the impurity for doping.

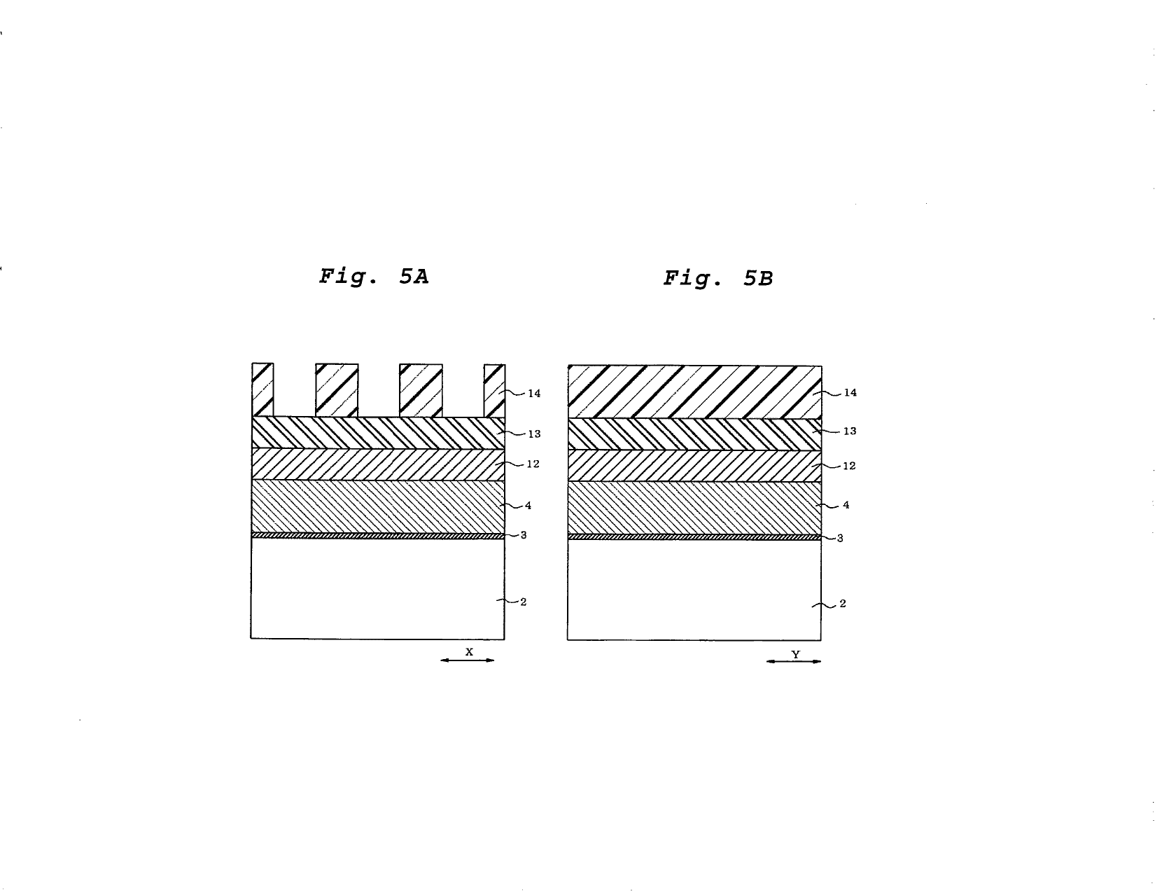

Then, as shown in FIG. 5A and FIG. 5B, on the polysilicon layer 4, a nitride film 12 is deposited at an appropriate film thickness using the LP-CVD method. On the nitride film 12, an oxide film 13 is then deposited onto an appropriate film thickness using the chemical vapor deposition method. Then, on the oxide film 13, a resist 14 is coated, followed by exposure and development to pattern the resist 14. In this case, the resist 14 is patterned to form a line-and-space pattern with a designated spacing.

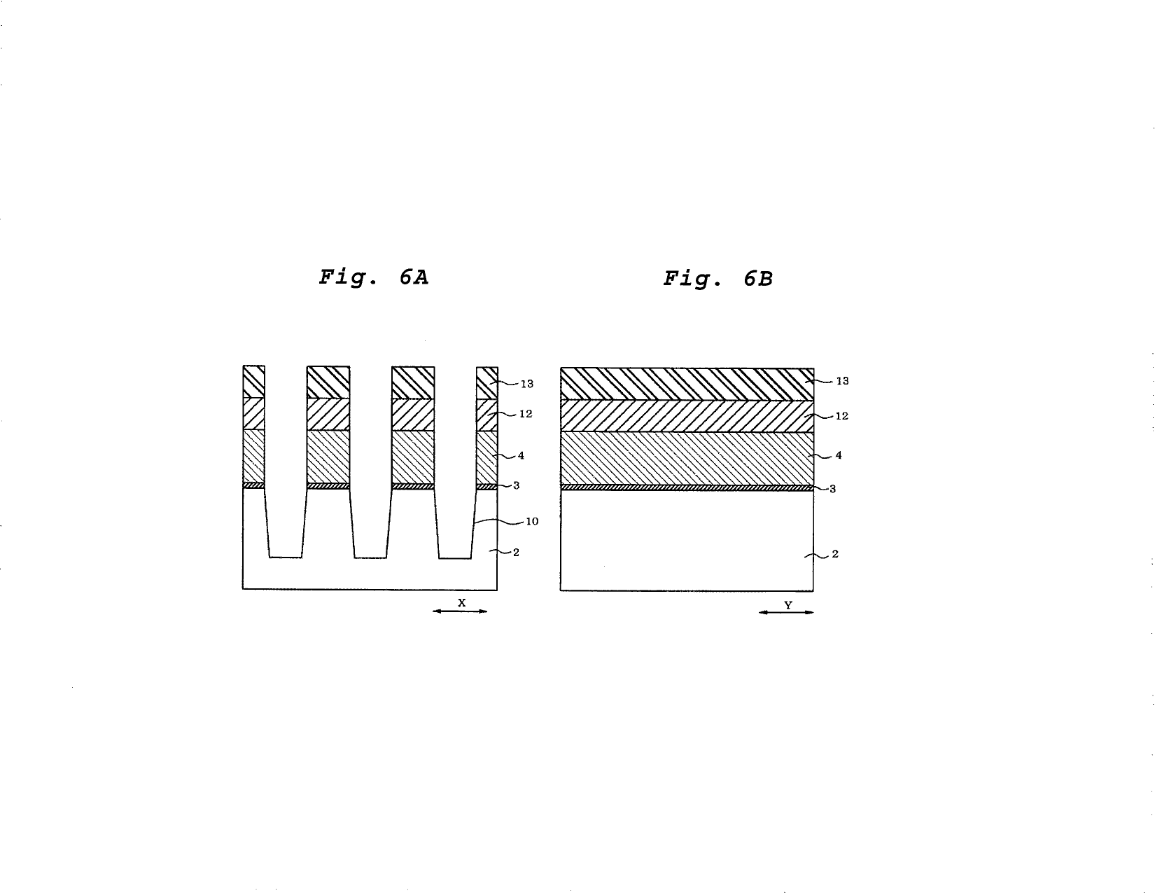

Then, as shown in FIG. 6A and FIG. 6B, the patterned resist 14 is taken as a mask, and the oxide film 13 is etched by the RIE (Reactive Ion Etching) method. After etching, the photoresist 14 is removed. With the oxide film 13 taken as a mask, the nitride film 12 is etched. Then, the polysilicon layer 4, gate insulating film 3, and the upper portion of the semiconductor substrate 2 are etched with a designated spacing to form the element separating trenches 10.

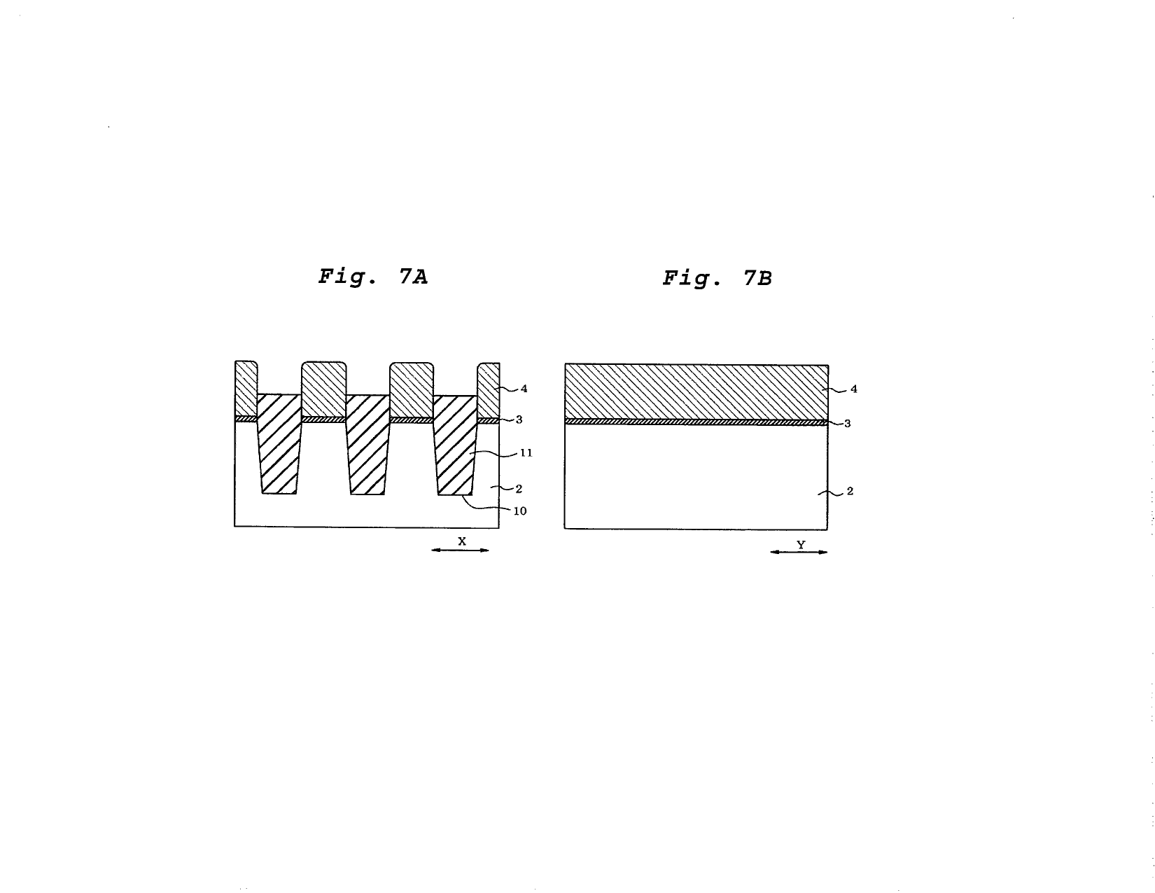

Then, as shown in FIG. 7A and FIG. 7B, by means of depositing technology and coating technology, etc., the element separating insulating film 11 (e.g., oxide film or the like) is buried in the element separating trench 10. Flattening is then carried out for the element separating insulating film 11 using the CMP (chemical mechanical polishing) method until the upper surface of the nitride film is exposed. Then, the upper surface of the element separating insulating film 11 is selectively etched, so that the element separating insulating film 11 is etched until its upper portion falls to the position lower than the upper surface of the polysilicon layer 4 and higher than the upper surface of the gate insulating film 3. The nitride film 12 left on the polysilicon layer 4 is then selectively etched off by, for example, wet etching.

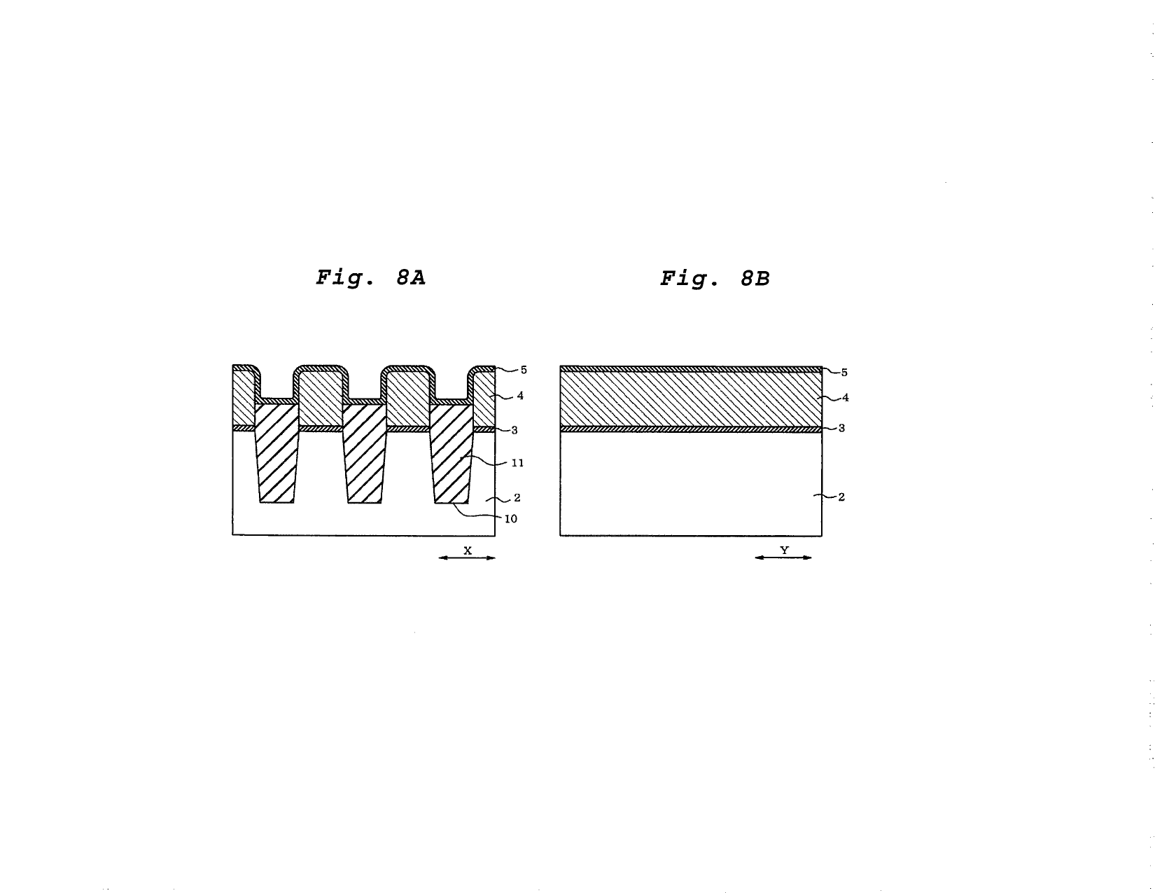

Then, as shown in FIG. 8A and FIG. 8B, the inter-electrode insulating film 5 is formed along the upper surface and the side surface of the upper portion of the polysilicon layer 4 and the upper surface of the element separating insulating film 11. This inter-electrode insulating film 5 has a laminated structure of oxide film/nitride film/oxide film and is formed in a well-known process. One may also use a scheme in which an NONON film is formed by performing a radical nitriding treatment before and after formation of the ONO film as the inter-electrode insulating film 5. Moreover, one may also use a scheme in which, instead of the middle nitride film, a high-dielectric-constant film containing aluminum oxide (alumina) or hafnium oxide is formed.

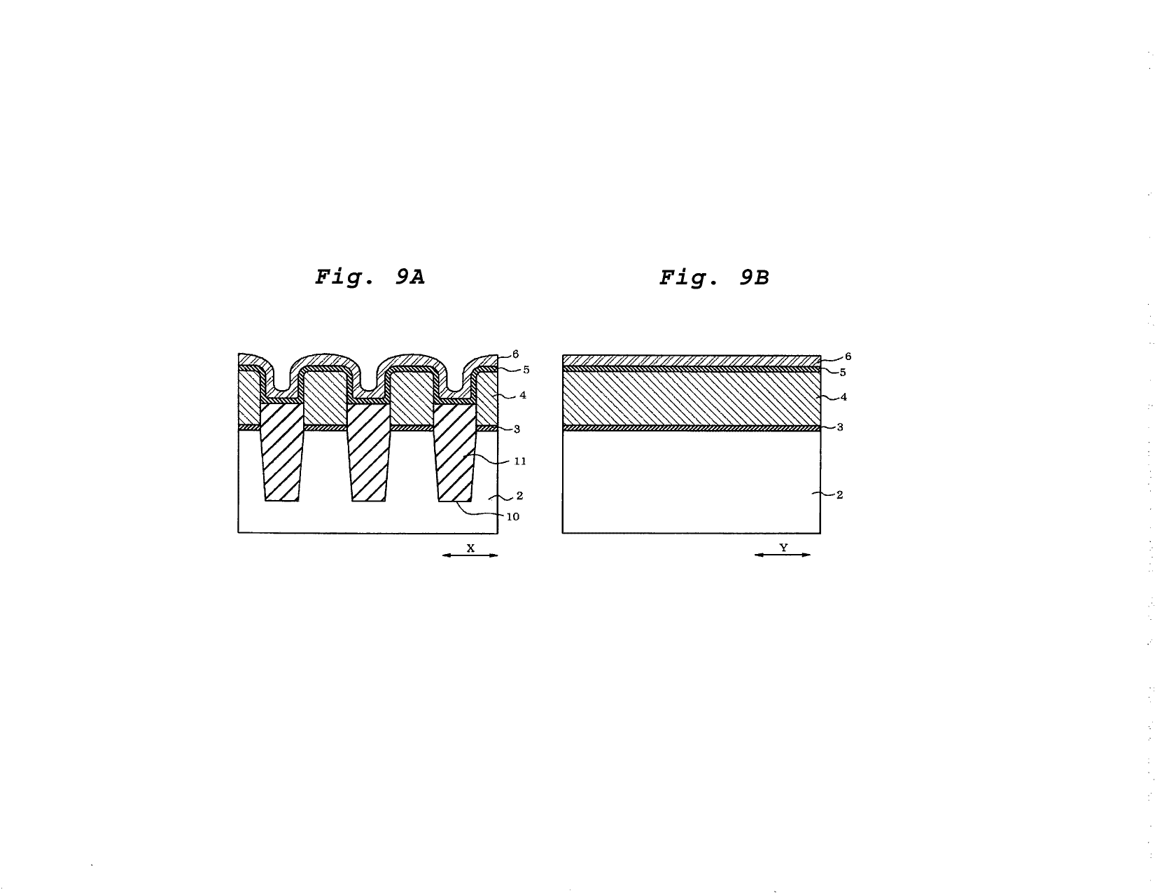

Then, as shown in FIG. 9A and FIG. 9B, silicon that forms the word lines WL and a portion of the control gate electrodes CG is deposited as the lower layer 6 using the LP-CVD method. In this case, the film formation conditions should be appropriate so that silicon is deposited while phosphine (PH₃) gas for doping phosphorus (P) and the monosilane (SiH₄) into the reaction oven and, at the same time, the designated reduced pressure state is maintained in the reaction oven. For example, the film formation parameters may be a temperature of 525° C., a pressure of 53 Pa, a monosilane flow rate of 500 cc, and a phosphine flow rate of 47.2 cc.

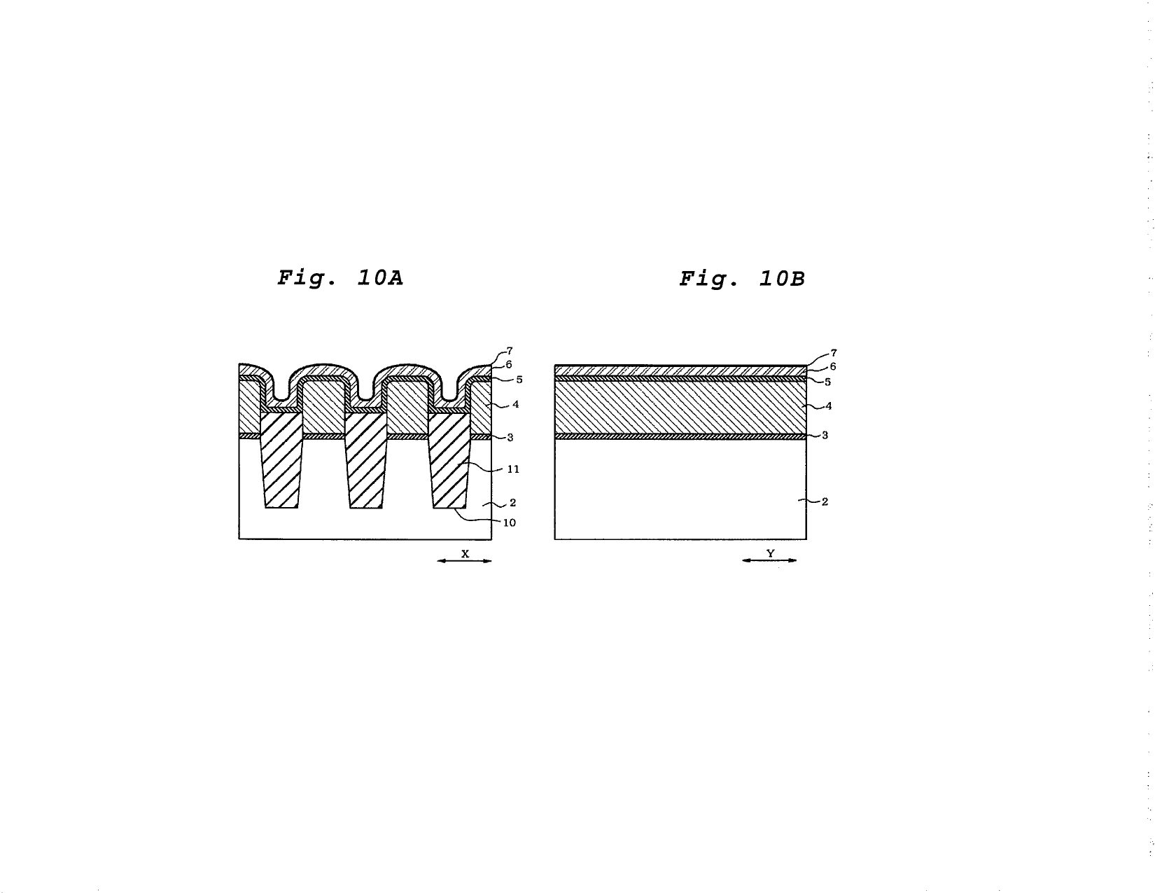

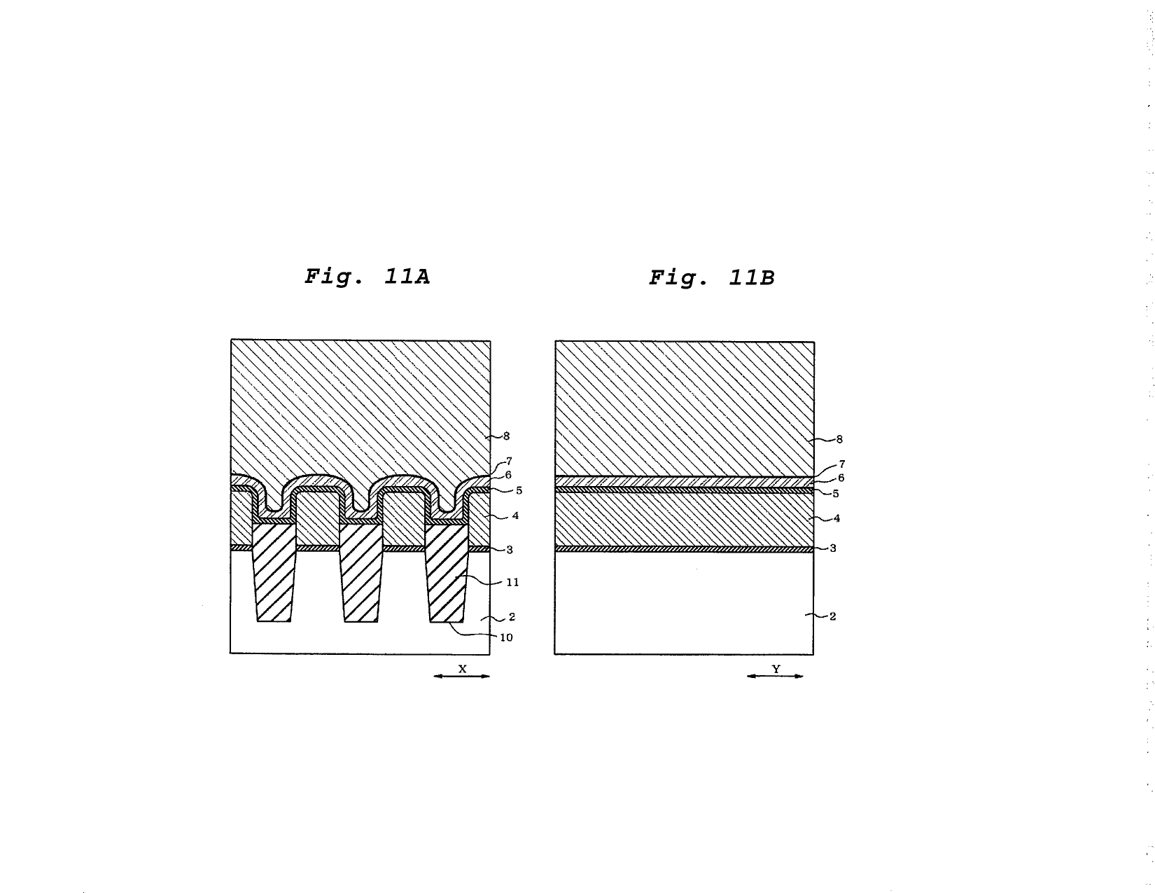

After the lower layer 6 with the desired film thickness is deposited, the film formation operation is stopped and the atmosphere in the chamber is replaced by oxygen (O₂), with oxygen (O₂) purge performed for 2 min. As a result, as shown in FIG. 10A and FIG. 10B, the separating layer 7 can be formed as a layer containing oxygen (O) on the lower layer 6. The film thickness of the separating layer 7 is from 2 to 8 Å (e.g., 5 Å), and it is a much thinner film than the other functional films (such as silicon lower layer 6, upper layer 8, inter-electrode insulating film 5, etc.). After oxygen (O₂) purge, the film formation conditions are reset, and, as shown in FIG. 11A and FIG. 11B, the upper layer 8 with the desired film thickness is formed. The film formation conditions for the upper layer 8 are the same as those for the lower layer 6. According to the present embodiment, the film thickness of the upper layer 8 is about 8 to 12 times (e.g., 10 times) that of the lower layer 6.

Before and after the oxygen (O₂) purge, evacuation of the interior of the chamber is carried out for a total time of about 5 min. With the film formation conditions of the present embodiment, it is possible to form the lower layer 6, separating layer 7, and upper layer 8 continuously in the same chamber. For the lower layer 6 and upper layer 8 of silicon formed under these temperature conditions, although they are in an amorphous state right after deposition, they are converted to polysilicon in the later heat treatment operation.

According to the present embodiment, the lower layer 6 is thin, and it is hard to grow the crystals from the lower side to the upper side of the separating layer 7. By arranging the separating layer 7, it is possible to set a crystal grain boundary (Grain Boundary) between the silicon lower layer 6 and upper layer 8. As a result, in particular, the mean value of the crystal grain size of the polysilicon lower layer 6 can be decreased. As a result, in particular, it is possible to suppress depletion of the lower layer 6. The proportion of the grain boundary per unit volume of polysilicon increases, the phosphorus (P) or some other impurity can easily remain in the polysilicon lower layer 6, and the proportion of the carrier increases.

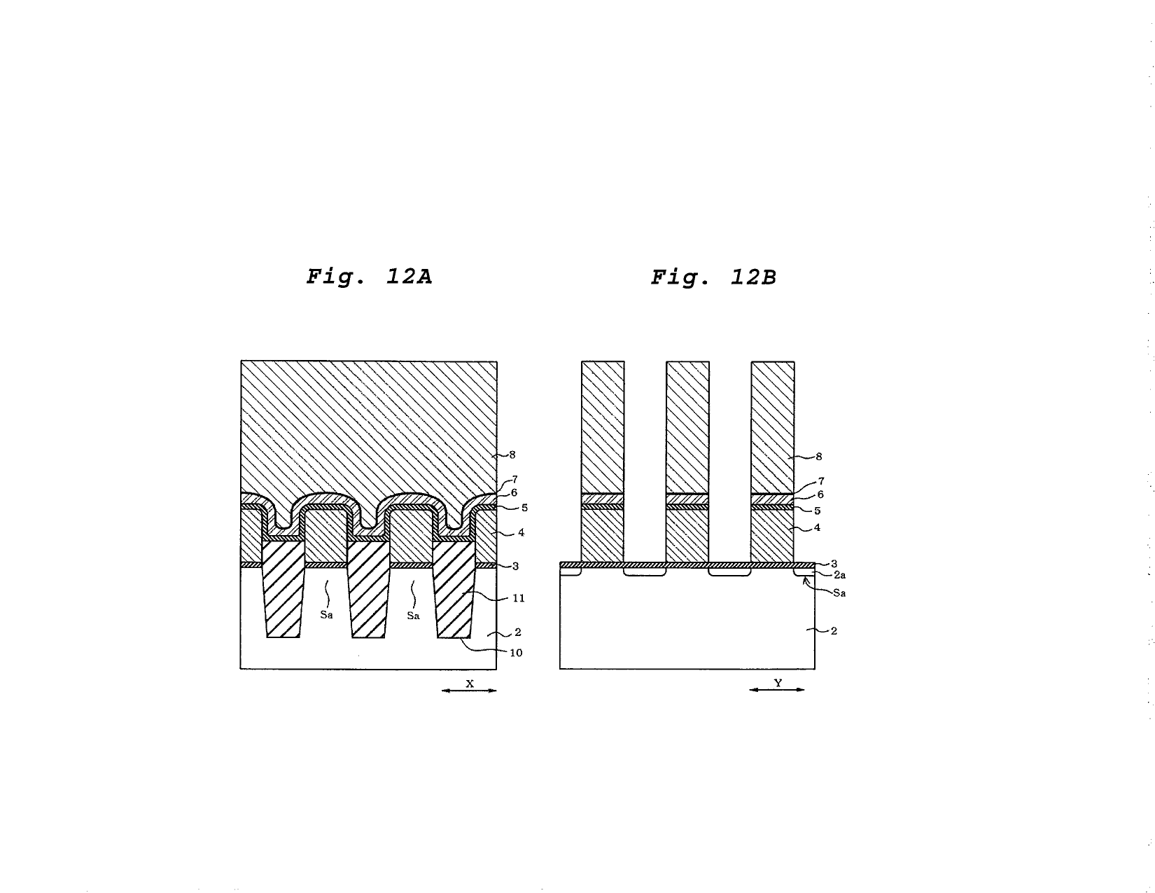

Then, on the silicon upper layer 8, a resist is coated to form a mask pattern (not shown in the figure) and, as shown in FIG. 12A and FIG. 12B, anisotropic etching is carried out to separate the upper layer 8, separating layer 7, lower layer 6, inter-electrode insulating film 5, polysilicon layer 4, and, as needed, the gate insulating film 3, and the mask pattern is removed. Then, an n-type impurity is ion implanted into the surface layer of the semiconductor substrate 2 between the separated laminated films 4 to 8. The ion implanted impurity is then activated, and this region is formed as source/drain regions 2a.

Then, between the separated laminated films 4 to 8, interlayer insulating film is buried (not shown in the figure). Next, as shown in FIG. 3A and FIG. 3B, the upper portion of the silicon upper layer 8 is silicided to form the silicide layer 9. Depending on the silicided metal material, for the silicide layer 9, one may also use a scheme in which siliciding may also be carried out for the silicon lower layer 6 in addition to the entirety of the silicon upper layer 8, and siliciding of the silicon upper layer 8 may also be stopped by the separating layer 7.

For the later manufacturing operation, as it is irrelevant to the characteristic features of the present embodiment, no detailed explanation will be given. However, the bit line contacts CB and other contacts, multilayer wiring structure, etc., are used in the structure. In the later manufacturing operation, as it is not specifically related to the characteristic features of the embodiment, it will not be explained. In this way, the NAND type flash memory device 1 is formed.

As explained above, according to the present embodiment, when the separating layer 7 containing oxygen is formed on the silicon lower layer 6, the separating layer 7 is formed as the atmosphere is replaced by the oxygen (O₂) atmosphere halfway during the deposition of silicon. As a result, the silicon crystal can hardly be grown from the lower side to the upper side of the separating layer 7, and it is possible to arrange a crystal grain boundary between the silicon lower layer 6 and the upper layer 8 by forming the separating layer 7.

As a result, in particular, the mean value of the crystal grain size of the polysilicon lower layer 6 can be decreased, and the proportion of the grain boundary per unit volume of the polysilicon increases. There is a tendency that phosphorus (P) or some other impurity will be transferred to the grain boundary of the polysilicon and remain in the polysilicon. Consequently, phosphorus (P) or some other impurity tends to remain in the polysilicon lower layer 6, and the proportion of the effective carrier increases. As a result, it is possible to suppress the electric depletion of the lower layer 6.

Because the separating layer 7 is located between the adjacent floating gate electrodes FG-FG, the space between the separating layer 7, which is located between the floating gate electrodes FG-FG and the inter-electrode insulating film 5 becomes smaller; even when silicon that forms the lower layer 6 is crystallized, the mean grain size becomes smaller.

### Other Embodiments

In the explanation of the embodiment, the sample is exposed to an oxygen (O₂) atmosphere and oxygen (O₂) purge is carried out so that an oxygen-containing layer is formed as the separating layer 7. However, the embodiment is not limited to this scheme. One may also use a process in which the sample is exposed to a nitrogen (N₂) atmosphere, and nitrogen (N₂) purge is carried out to form a nitrogen-containing layer as the separating layer 7. When the nitrogen (N₂) purge is carried out, the temperature should be in the range of about 900° C. to 1000° C.

In this embodiment, the film thickness of the upper layer 8 is about 10 times the thickness of the lower layer 6. However, the embodiment is not limited to this structure. As long as the film thickness of the upper layer 8 is larger than the thickness of the lower layer 6, the lower layer 6 may have a smaller polysilicon grain size.

When the silicon lower layer 6 and upper layer 8 are deposited, one may also use a scheme in which carbon or some other ingredient is doped to decrease the grain size of the polysilicon. Moreover, the silicide layer 9 for forming the control gate electrode CG may either be arranged or not arranged.

In the above, the principal ingredient is applied on a NAND type flash memory device 1. However, it may also be used in a NOR type flash memory device, EEPROM, and other types of semiconductor storage devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a nonvolatile semiconductor storage device, comprising the steps of:
forming a gate insulating film on a semiconductor substrate;
forming multiple floating gate electrodes on the gate insulating film;
forming an inter-electrode insulating film on the multiple floating gate electrodes; and
forming word lines containing polysilicon doped with an impurity on the inter-electrode insulating film, the word lines including a lower layer, an upper layer, and a separating layer between the lower layer and the upper layer.

2. The method of claim 1, wherein the separating layer is formed between the multiple floating gate electrodes.

3. The method of claim 1, wherein the upper layer of the word line is formed to be higher than the lower layer of the word line.

4. The method according to claim 1, wherein the separating layer is an oxygen containing layer.

5. The method according to claim 4, wherein the separating layer is formed by substituting the atmosphere during the step of forming word lines with an oxygen atmosphere.

6. The method according to claim 5, wherein the atmosphere is substituted with the oxygen atmosphere halfway through the step of forming word lines.

7. The method according to claim 1, wherein the separating layer is a nitrogen containing layer.

8. The method according to claim 7, wherein the separating layer is formed by substituting the atmosphere during the step of forming word lines with a nitrogen atmosphere.

9. The method according to claim 8, wherein the atmosphere is substituted with the nitrogen atmosphere halfway through the step of forming word lines.

10. The method according to claim 1, wherein the ratio of the height of the upper layer to the height of the lower layer is about 10:1.

11. A nonvolatile semiconductor storage device comprising:
a semiconductor substrate;
a gate insulating film formed on the semiconductor substrate;
multiple floating gate electrodes formed on the gate insulating film;
an inter-electrode insulating film formed on the multiple floating gate electrodes; and
word lines formed on the inter-electrode insulating film, the word lines having upper and lower layers containing polysilicon doped with an impurity, and a separating layer that separates the upper layer and the lower layer.

12. The nonvolatile semiconductor storage device according to claim 11, wherein the separating layer has a portion located between the multiple floating gate electrodes.

13. The nonvolatile semiconductor storage device according to claim 11, wherein the height of the lower layer is less than the height of the upper layer.

14. The nonvolatile semiconductor storage device according to claim 13, wherein the height of the upper layer is about 10 times more than the height of the lower layer.

15. The nonvolatile semiconductor storage device according to claim 13, wherein the separating layer comprises a silicon oxide layer.

16. The nonvolatile semiconductor storage device according to claim 13, wherein the separating layer comprises a silicon nitride layer.

17. A nonvolatile semiconductor storage device comprising:
a semiconductor substrate;
a gate insulating film formed on the semiconductor substrate;
multiple floating gate electrodes formed on the gate insulating film;
an inter-electrode insulating film formed on the multiple floating gate electrodes; and
word lines formed on the inter-electrode insulating film, the word lines having upper and lower layers containing polysilicon doped with an impurity, and a separating layer formed of one of silicon oxide and silicon nitride that separates the upper layer and the lower layer.

18. The nonvolatile semiconductor storage device according to claim 17, wherein separating layer has a thickness of about 2 Å to about 8 Å.

18. The nonvolatile semiconductor storage device according to claim 17, wherein the upper layer is thicker than the lower layer.

19. The nonvolatile semiconductor storage device according to claim 18, wherein the upper layer is thicker than the lower layer by about 8 times to about 12 times.

20. The nonvolatile semiconductor storage device according to claim 19, wherein the separating layer is located between the multiple floating gate electrodes.
